(19) United States
(12) Patent Application Publication
(10) Pub. No.: US 2015/0155686 A1
(43) Pub. Date: Jun. 4, 2015

(54) OPERATING VERTICAL-CAVITY SURFACE-EMITTING LASERS

(71) Applicants: Daniel A. Berkram, Loveland, CO (US); Dacheng Zhou, Fort Collins, CO (US); Zhubiao Zhu, Fort Collins, CO (US)

(72) Inventors: Daniel A. Berkram, Loveland, CO (US); Dacheng Zhou, Fort Collins, CO (US); Zhubiao Zhu, Fort Collins, CO (US)

(21) Appl. No.: 14/379,554

(22) PCT Filed: Apr. 25, 2012
(86) PCT No.: PCT/US12/34907

§ 371 Date: Aug. 19, 2014

(51) Int. Cl. H01S 5/042; H01S 5/183

(52) U.S. Cl. CPC H01S 5/042; H01S 5/183

(57) ABSTRACT

Methods, systems, and devices are provided for operating a vertical-cavity surface-emitting laser. Operating a vertical-cavity surface-emitting laser can include determining an output voltage of a vertical-cavity surface-emitting laser driver, determining a relationship between the output voltage and a reference voltage, and adjusting an output current of the vertical-cavity surface-emitting laser driver based, at least in part, on the determined relationship.

### BACKGROUND

Optical power in a vertical-cavity surface-emitting laser (VCSEL) can vary (e.g., as temperature changes). To reduce power consumption and/or increase reliability of VCSELs, power may be controlled automatically, in some instances.

### BRIEF DESCRIPTION OF THE DRAWING

FIG. 1 illustrates a block diagram of an example of a system for operating a VCSEL in accordance with the present disclosure.

FIG. 2 illustrates an example of a system including an optical power control circuit for operating a VCSEL in accordance with the present disclosure.

FIG. 3 illustrates a block diagram of an example of a computing system including a computer-readable medium in communication with processing resources for operating a VCSEL in accordance with the present disclosure.

FIG. 4 is a flow chart illustrating an example of a method for operating a VCSEL in accordance with the present disclosure.

### DETAILED DESCRIPTION

Examples of the present disclosure include methods, systems, and/or devices. An example method for operating a VCSEL can include determining an output voltage of a vertical-cavity surface-emitting laser driver, determining a relationship between the output voltage and a reference voltage, and adjusting an output current of the vertical-cavity surface-emitting laser driver based, at least in part, on the determined relationship.

Existing techniques for automatically controlling power may include the use of monitoring systems (e.g., external systems) employing a monitoring laser and/or monitoring photodiode. Such systems may additionally include complicated circuits which may further increase costs. Further, such systems may rely on assumptions that various characteristics between the monitoring system and VCSEL system are shared (e.g., operating temperature, mechanical alignment, and/or aging behavior).

In the following detailed description of the preset disclosure, reference is made to the accompanying drawings that form a part hereof, and in which is shown by way of illustration how examples of the disclosure can be practiced. These examples are described in sufficient detail to enable those of ordinary skill in the art to practice the examples of this disclosure, and it is to be understood that other examples can be utilized and that process, electrical, and/or structural changes can be made without departing from the scope of the present disclosure.

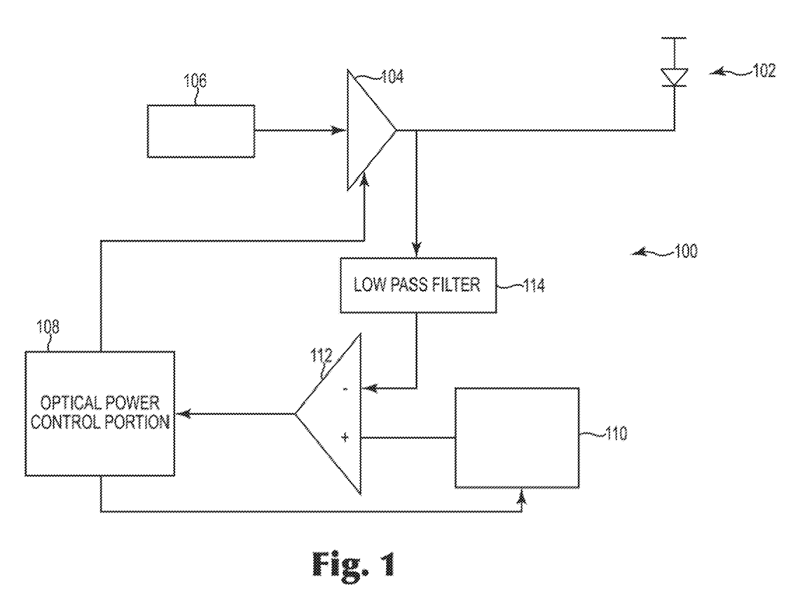

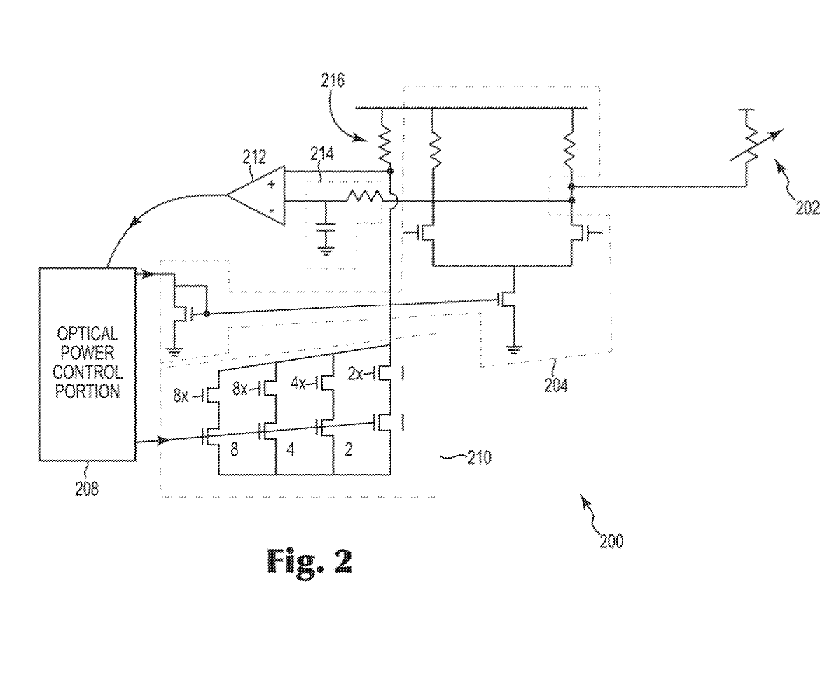

The figures herein follow a numbering convention in which the first digit or digits correspond to the drawing figure number and the remaining digits identify an element or component in the drawing. Similar elements or components between different figures may be identified by the use of similar digits. For example, 110 may reference element “10” in FIG. 1, and a similar element may be referenced as 210 in FIG. 2. Elements shown in the various figures herein can be added, exchanged, and/or eliminated so as to provide a number of additional examples of the present disclosure. In addition, the proportion and the relative scale of the elements provided in the figures are intended to illustrate the examples of the present disclosure, and should not be taken in a limiting sense.

For various semiconductor diodes, junction voltage at a fixed current can decrease as temperature increases. For example, junction voltage in a VCSEL can vary such a manner (e.g., by −2-mV/° C.). Accordingly, as temperature increases, VCSEL modulated optical power can decrease as threshold current for stimulated emission increases. Such a decrease can be visualized by a slope efficiency curve flattening with increased temperature in a conceptual I-P curve illustrating a relationship between driving current and optical power in a VCSEL. Automatic power control schemes can maintain substantially constant optical power in the face of various changing conditions including, for example, temperature, component age, and/or alignment, among others.

Examples of the present disclosure do not use costly monitoring laser(s) and/or monitoring photodiode(s). Accordingly, examples of the present disclosure can save costs associated with such components, installation of such components, and/or additional complicated circuits that may be associated therewith.

Additionally, examples of the present disclosure can avoid using assumptions of model parameters. For example, monitoring voltage via a monitoring system may require knowledge of various parameters as well as their behaviors over various temperatures and/or over ages. Such knowledge may be costly to gain, and may vary from one VCSEL system to another. Accordingly, examples of the present disclosure can cover various (e.g., all) parts of a VCSEL system, photodiode, and/or path variations (e.g., alignment of transmitter and/or receiver and/or aging).

Additionally, examples of the present disclosure can use data from a VCSEL system itself rather than data from a number of monitoring systems. As a result, examples of the present disclosure can avoid issues associated with differing characteristic between multiple systems. Further, examples of the present disclosure can be implemented with reduced (e.g., minimal) changes to hardware (e.g., circuits) resulting in reduced space and/or power, for instance, compared to previous approaches to optical power control.

Examples of the present disclosure can monitor an output voltage (e.g., common mode voltage, of a VCSEL driver and compare it with a reference voltage. Accordingly, examples of the present disclosure can adjust an output current of the VCSEL driver and thereby adjust an optical power of a VCSEL transmitter (e.g., photodiode).

For example, examples of the present disclosure can adjust an output signal swing and/or common mode voltage associated with a transmitter. Accordingly, examples of the present disclosure can dynamically adjust VCSEL optical power, increasing VCSEL life and reliability, while still ensuring sufficient optical power to maintain transmission reception integrity.

FIG. 1 illustrates a block diagram of an example of a system 100 for operating a VCSEL 102 in accordance with the present disclosure. As shown in FIG. 1, system 100 includes a VCSEL 102, a driver portion 104, signal data 108, an optical power control portion 108, a reference voltage generation portion 110, a comparator 112 and a low pass filter portion 114. System 100 is not limited to the elements illustrated in FIG. 1; rather, system 100 can include additional elements such as for example, a number of power supplies, among others.

Optical power control portion 108 can be implemented in the form of, and/or include, for example, hardware (e.g., control) logic (e.g., in the form of application specific integrated circuits (ASICs)). However, examples of the present disclosure are not limited to a particular implementation of optical power control portion 108 unless otherwise indicated.

VCSEL 102 can include a transmitter and/or a receiver (not illustrated in FIG. 1). The transmitter and the receiver can reside in separate sub-networks within an optical network such that they may be in separate interconnected rings and/or in a mesh network that may be coupled together by a number of optical fibers, for instance. The transmitter can be a VCSEL diode (e.g., semiconductor laser diode with laser transmission perpendicular to its top surface). For example, the transmitter can transmit an optical signal (e.g., transmission, light wave and/or pulse) at various optical power levels. The optical power level of the transmitter can be controlled (e.g., increased, decreased, maintained, and/or regulated) by driver portion 104, for instance, discussed further below.

The receiver can be a device and/or module (e.g., a photodetector) configured to receive an optical signal from the transmitter. For example, the receiver can be positioned to receive an optical signal directed toward the receiver from the transmitter. The receiver can be of various types including, for example a positive, intrinsic, and negative photodiode and/or resonant cavity photodetector, among others.

As previously discussed, a particular optical power level of the optical signal (e.g., transmission) can allow signal reception by the receiver with sufficient integrity. Sufficient integrity can be measured by a bit error rate (e.g., a bit error rate of received signal data 106). The optical power of the signal from the transmitter can be increased such that an expected bit error rate exceeds a threshold, is at a particular level (e.g., 10⁻¹²) and/or falls within a particular range (e.g., 10⁻¹⁰-10⁻¹⁶) and/or signal integrity margin.

However, and as previously discussed, optical power can decrease as temperature increases. Such a decrease in optical power can result from a forward voltage decrease because, for example, resistance associated with (e.g., across) VCSEL 102 can change with temperature (e.g., VCSEL resistance decreases with increased temperature). Further, because a supply voltage of driver portion 104 can remain constant, an output voltage of driver portion 104 can decrease as temperature increases.

Accordingly, examples of the present disclosure can determine (e.g., monitor) output voltage of driver portion 104 and compensate for various changes in output voltage of driver portion 104 caused by, for example, temperature changes. Such compensation can ensure that optical power of VCSEL 102 exceeds a threshold (e.g., is sufficient for reliable reception of transmitted signal data 106). Further, once determined, output voltage can allow examples of the present disclosure to determine (e.g., estimate) a voltage of VCSEL 102, thereby allowing determination (e.g., estimation) of a temperature (e.g., actual temperature) of VCSEL 102.

Determining output voltage of driver portion 104 can include comparing output voltage of driver portion 104 to a reference voltage. Accordingly, a reference voltage can be determined (e.g., set) by optical power control portion 108. Further, a determined reference voltage can be generated by reference voltage generation portion 110. For example, optical power control portion 108 can determine a reference voltage based on a particular output voltage of driver portion 104 determined (e.g., known) to be sufficient such that associated optical power of VCSEL 102 is sufficient for reliable reception (e g., reception of sufficient integrity and/or quality at a particular temperature). For example, optical power control portion 108 can determine that a reception is sufficiently reliable if it exceeds a particular threshold (e.g., bit error rate). For example, optical power control portion 108 can receive various inputs from a receiver of VCSEL 102 associated with reliability of reception of signal data 106.

Further, optical power control portion 108 can determine the reference voltage based on a particular temperature (e.g., an operating temperature of system 100 and/or VCSEL 102). For example, optical power control portion 108 can access various data (e.g., a table) correlating temperature(s) with forward voltage of VCSEL 102 and/or output voltage of driver portion 104. Optical power control portion 108 can use such data to determine a reference voltage (e.g., a baseline reference voltage) to be generated by voltage generation portion 110, for instance.

The reference voltage generated by reference voltage generation portion 110 can be received by (e.g., fed into) comparator 112 (e.g., a positive input of comparator 112) as shown in FIG. 1. An example of circuitry to generate the reference voltage is illustrated in FIG. 2. Comparator 112 can also receive (e.g., at a negative input of comparator 112) the output voltage of driver portion 104. As shown in FIG. 1, the output voltage of driver portion 104 can be low-pass filtered by low pass filter portion 114 before being received by comparator 112. Additionally, low pass filter portion 114 can, for example, be used to obtain various voltage information such as average common mode voltage from driver portion 104 through low pass filter portion 114.

Comparator 112 can compare the output voltage of driver portion 104 with the reference voltage generated by reference voltage generation portion 110. Accordingly, comparator 112 can determine a relationship between the output voltage of driver portion 104 and the reference voltage. For example, comparator 112 can determine that the output voltage of driver portion 104 exceeds the reference voltage (e.g., by a particular amount). Additionally, comparator 112 can determine that the output voltage of driver portion 104 is less than the reference voltage (e.g., by a particular amount). Additionally, comparator 112 can determine that the output voltage of driver portion 104 is equal (e.g., substantially equal) to the reference voltage.

The determined relationship between the output voltage of driver portion 104 and the reference voltage can be received by optical power control portion 108. Output power control portion 108 can make various determinations and/or can send various signals (e.g., requests) to driver portion 104 based on the relationship. For example, if the output voltage of driver portion 104 exceeds the reference voltage, optical power control portion 108 can determine that the optical power of VCSEL 102 is elevated (e.g., higher than required for reliable reception). Accordingly, optical power control portion 108 can send a signal to driver portion 104 to decrease (e.g., by a particular amount and/or portion) an output current of driver portion 104, which can thereby reduce the optical power of VCSEL 102. As previously discussed, an elevated optical power can alter (e.g., shorten) a lifespan of VCSEL 102, for instance.

Alternatively, if the output voltage of driver portion 104 is less than the reference voltage, optical power control portion 108 can determine that the optical power of VCSEL 102 is insufficient (e.g., lower than required for reliable reception). Accordingly, optical power control portion 108 can send a signal to driver portion 104 to increase (e.g., by a particular amount and/or portion) an output current of driver portion 104, which can thereby increase the optical power of VCSEL 102. As previously discussed, insufficient optical power can result in unreliable reception of signal data 106.

Alternatively, if the output voltage of driver portion 104 is equal to the reference voltage, optical power control portion 108 can determine that the optical power of VCSEL 102 is appropriate (e.g., appropriate to increase VCSEL life and/or appropriate to ensure sufficient optical power to maintain transmission reception integrity). Accordingly, optical power control portion 108 can send a signal to driver portion 104 to maintain (e.g., hold at a particular level) output voltage because, for example, output voltage of driver portion 104 may not necessitate immediate adjustment.

As previously discussed, a determined, output voltage can allow examples of the present disclosure (e.g., optical power control portion 108) to determine (e.g., estimate) a voltage of VCSEL 102, thereby allowing determination (e.g., estimation) of a temperature (e.g., actual temperature) of VCSEL 102.

Determining (e.g., estimating) temperature of VCSEL 102 can enhance an ability of optical power control portion 108 to control (e.g., increase, decrease, and/or maintain) optical power of the transmitter of VCSEL 102. For example, an elevated temperature of VCSEL 102 can trigger optical power control portion 108 to reduce a rate of transmission (e.g., reduce rate of data packet transmission) of signal data 106. Further, determining temperature of VCSEL 102 can allow activation of various systems. For example, optical power control portion 108 can determine that a temperature of VCSEL 102 exceeds a threshold (e.g., is elevated) and can activate a cooling system (e.g., a number of fans, water cooling systems, and/or thermoelectric devices) to reduce the temperature of VCSEL 102.

FIG. 2 illustrates an example of a system 200 including an optical power control circuit (e.g., an example circuit) for operating a VCSEL 202 in accordance with the present disclosure. In a manner analogous to system 100 previously discussed in connection with FIG. 1, system 200 includes a VCSEL 202, a driver portion 204, an optical power control portion 208, a reference voltage generation portion 210, a comparator 212 and a low pass filter portion 214. Also illustrated in FIG. 2 is a resistor 216, which can be a part of reference voltage generation portion 210, for instance. System 200 is not limited to the devices and/or elements (and/or amounts thereof) illustrated in FIG. 2; rather, system 200 can include additional elements and/or alternative elements. For example, system 200 can include a number of power supplies, among others.

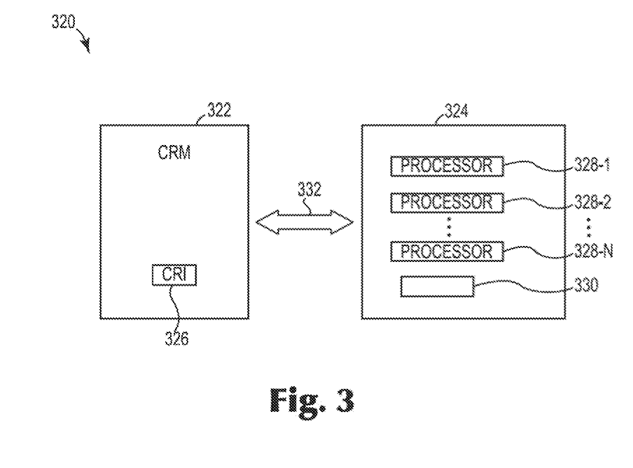

FIG. 3 illustrates a block diagram 320 of an example of a computing system including a computer-readable medium 322 in communication with processing resources for operating a VCSEL in accordance with the present disclosure. Computer-readable medium (CRM) 322 can be in communication with a computing device 324 having processor resources of more or fewer than 328-1, 328-2, . . . , 328-N, that can be in communication with, and/or receive a tangible non-transitory CRM 322 storing a set of computer-readable instructions 326 executable by one or more of the processor resources (e.g., 328-1, 328-2, . . . , 328-N) for operating a VCSEL as described herein. The computing device may include memory resources 330, and the processor resources 328-1, 328-2, . . . , 328-N may be coupled to the memory resources 330.

Processor resources can execute computer-readable instructions 326 for operating a VCSEL that are stored on an internal or external non-transitory CRM 322. A non-transitory CRM (e.g., CRM 322), as used herein, can include volatile and/or non-volatile memory. Volatile memory can include memory that depends upon power to store information, such as various types of dynamic random access memory (DRAM), among others. Non-volatile memory can include memory that does not depend upon power to store information. Examples of non-volatile memory can include solid state media such as flash memory, EEPROM, phase change random access memory (PCRAM), magnetic memory such as a hard disk, tape drives, floppy disk, and/or tape memory, optical discs, digital video discs (DVD), Blu-ray discs (BD), compact discs (CD), and/or a solid state drive (SSD), flash memory, etc., as ell as other types of CRM.

Non-transitory CRM 322 can be integral, or communicatively coupled, to a computing device, in either in a wired or wireless manner. For example, non-transitory CRM 322 can be an internal memory, a portable memory, a portable disk, or a memory located internal to another computing resource (e.g., enabling the computer-readable instructions to be downloaded over the Internet).

CRM 322 can be in communication with the processor resources (e.g., 328-1, 328-2, . . . , 328-N) via a communication path 332. The communication path 332 can be local or remote to a machine associated with the processor resources 328-1, 328-2, . . . , 328-N. Examples of a local communication path 332 can include an electronic bus internal to a machine such as a computer where CRM 322 is one of volatile, non-volatile, fixed, and/or removable storage medium in communication with the processor resources (e.g., 328-1, 328-2, . . . , 328-N) via the electronic bus. Examples of such electronic buses can include Industry Standard Architecture (ISA), Peripheral Component Interconnect (PCI), Advanced Technology Attachment (ATA), Small Computer System Interface (SCSI), Universal Serial Bus (USB), among other types of electronic buses and variants thereof.

Communication path 332 can be such that CRM 322 is remote from the processor resources (e.g., 328-1, 328-2, . . . , 328-N) such as in the example of a network connection between CRM 322 and the processor resources (e.g., 328-1, 328-2, . . . , 328-N). That is, communication path 332 can be a network connection. Examples of such a network connection can include a local area network (LAN), a wide area network (WAN), a personal area network (PAN), and the Internet, among others. In such examples, CRM 322 may be associated with a first computing device and the processor resources (e.g., 328-1, 328-2, . . . , 328-N) may be associated with a second computing device.

Computer-readable instructions 326 can include instructions to determine a reference voltage in a manner analogous to that discussed in connection with FIG. 1, for example.

Computer-readable instructions 326 can include instructions to request a vertical-cavity surface-emitting laser driver to adjust (e.g., increase, decrease, and/or maintain) an output voltage of the driver in response to receiving a signal from a comparator associated with a relationship between a reference voltage and an output voltage of a VCSEL driver (e.g., the reference voltage exceeds the output voltage, is less than the output voltage, and/or is substantially equal to the output voltage). Such requesting can be analogous to that previously discussed in connection with FIG. 1, for instance.

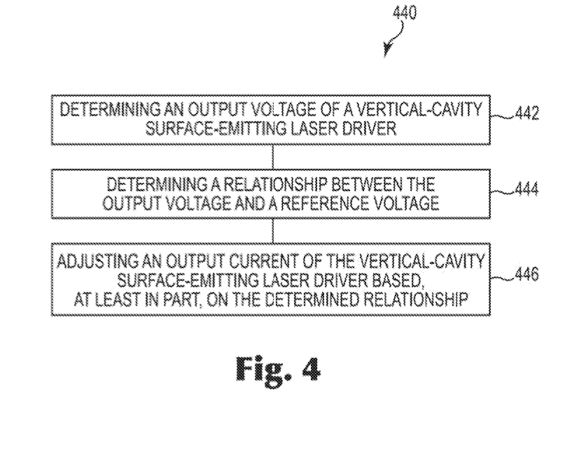

FIG. 4 is a flow chart illustrating an example of a method 440 for operating a VCSEL in accordance with the present disclosure. Method 440 can be performed by a number of hardware devices and/or a number of computing devices executing computer-readable instructions (e.g., the computing system discussed above in connection with FIG. 3).

At block 442, method 440 includes determining an output voltage of a vertical-cavity surface-emitting laser driver. An output voltage of a VCSEL can be determined in various manners such as, for example, those previously discussed in connection with FIG. 1.

At block 444, method 440 includes determining a relationship between the output voltage and a reference voltage. A relationship can be determined in a manner analogous to that previously discussed in connection with FIG. 1, for instance.

At block 446, method 440 includes adjusting an output current of the vertical-cavity surface-emitting laser driver based, at least in part, on the determined relationship. An output current can be adjusted in various manners, such as those previously discussed in connection with FIG. 1, for instance.

Method 440 can be performed at various stages of operation of a VCSEL (e.g., continuously and/or according to a schedule). Additionally, method 440 can be performed without an interruption of a transmission of a VCSEL signal.

The above specification, examples and data provide a description of the method and applications, and use of the system and method of the present disclosure. Since many examples can be made without departing from the spirit and scope of the system and method of the present disclosure, this specification merely sets forth some of the many possible example configurations and implementations.

Although specific examples have been illustrated and described herein, those of ordinary skill in the art will appreciate that an arrangement calculated to achieve the same results can be substituted for the specific examples shown. This disclosure is intended to cover adaptations or variations of one or more examples of the present disclosure. It is to be understood that the above description has been made in an illustrative fashion, and not a restrictive one. Combination of the above examples, and other examples not specifically described herein will be apparent to those of skill in the art upon reviewing the above description. The scope of the one or more examples of the present disclosure includes other applications in which the above structures and methods are used. Therefore, the scope of one or more examples of the present disclosure should be determined with reference to the appended claims, along with the full range of equivalents to which such claims are entitled.

What is claimed:

1. A method for operating a vertical-cavity surface-emitting laser, comprising:
determining an output voltage of a vertical-cavity surface-emitting laser driver;
determining a relationship between the output voltage and a reference voltage; and
adjusting an output current of the vertical-cavity surface-emitting laser driver based, at least in part, on the determined relationship.

2. The method of claim 1, wherein the method includes increasing the output current of the vertical-cavity surface-emitting laser driver in response to determining that the reference voltage exceeds the output voltage.

3. The method of claim 1, wherein the method includes decreasing the output current of the vertical-cavity surface-emitting laser driver in response to determining that the output voltage exceeds the reference voltage.

4. The method of claim 1, wherein the method includes maintaining the output current of the vertical-cavity surface-emitting laser driver at a particular level in response to determining that the output voltage and the reference voltage are substantially equal.

5. The method of claim 1, wherein the method includes determining the reference voltage based on a particular output voltage of the vertical-cavity surface-emitting laser driver associated with a particular temperature.

6. The method of claim 1, wherein the method includes determining a temperature associated with the vertical-cavity surface-emitting laser based on the determined output voltage.

7. The method of claim 6, wherein the method includes:
determining that the temperature associated with the vertical-cavity surface-emitting laser exceeds a threshold; and
activating a cooling system associated with the vertical-cavity surface-emitting laser in response to determining that the temperature exceeds the threshold.

8. A device for operating a vertical-cavity surface-emitting laser, comprising:
an optical power control logic to:
determine a reference voltage; and
request a vertical-cavity surface-emitting laser driver to increase an output voltage of the driver in response to receiving a signal from a comparator that the reference voltage exceeds the output voltage.

9. The device of claim 8, wherein the device includes optical power control logic to request the driver to decrease an output voltage of the driver by a particular amount in response to receiving a signal from the comparator that the output voltage exceeds the reference voltage.

10. The device of claim 8, wherein the device includes optical power control logic to determine the reference voltage based on an input from a vertical-cavity surface-emitting laser receiver.

11. The device of claim 8, wherein the device includes optical power control logic to determine the reference voltage such that an expected bit error rate associated with a received optical signal of the vertical-cavity surface-emitting laser at a particular temperature exceeds a threshold.

12. A system for operating a vertical-cavity surface-emitting laser, comprising:
a driver to control an optical power level of a vertical-cavity surface-emitting laser transmitter;
a reference voltage generation portion to generate a reference voltage;
a comparator to:
receive an output voltage from the driver;
receive the reference voltage from the reference voltage generation portion; and
determine that the reference voltage exceeds the output voltage; and
an optical power control portion including control logic to send a signal to the driver to increase the optical power level based on the reference voltage exceeding the output voltage.

13. The system of claim 12, wherein the optical power control portion includes control logic to send a signal to the driver to increase the optical power level by a particular portion of the optical power level.

14. The system of claim 12, wherein the optical power control portion includes control logic to send a signal to the driver to increase the optical power level such that an expected bit error rate associated with the optical power level exceeds a threshold.

15. The system of claim 12, wherein the system includes a low-pass filter portion to filter the output voltage from the driver before the output voltage from the driver is received by the comparator.
